(19) United States
(12) Patent Application Publication
(10) Pub. No.: US 2023/0403910 A1
(43) Pub. Date: Dec. 14, 2023

(54) DISPLAY DEVICE

(71) Applicant: Samsung Display Co., Ltd., Yongin-si (KR)

(72) Inventors: Youngji Kim, Yongin-si (KR); Daesang Yun, Yongin-si (KR); Soyoung Lee, Yongin-si (KR); Younghoon Lee, Yongin-si (KR)

(21) Appl. No.: 18/326,968

(22) Filed: May 31, 2023

(30) Foreign Application Priority Data
Jun. 10, 2022 (KR) 10-2022-0071035
Jun. 27, 2022 (KR) 10-2022-0078476

(51) Int. Cl. H10K 59/80

(52) U.S. Cl. CPC H10K 59/873; H10K 2102/311

(57) ABSTRACT

A display device is disclosed. The display device includes a support substrate including a first portion and a second portion that are separated from each other, a substrate fixed to one surface of the second portion of the support substrate, and including a display area on the first portion of the support substrate, a peripheral area on the second portion of the support substrate, and a bending area connecting the display area to the peripheral area, and a display portion in the display area.

### CROSS-REFERENCE TO RELATED APPLICATIONS

This application claims priority to and the benefit of Korean Patent Application No. 10-2022-0071035, filed on Jun. 10, 2022, and Korean Patent Application No. 10-2022-0078476, filed on Jun. 27, 2022, in the Korean Intellectual Property Office, the entire disclosures of both of which are incorporated by reference herein.

### BACKGROUND

### 1. Field

One or more embodiments relate to a device, and more particularly, to a display device.

### 2. Description of the Related Art

Recently, electronic devices based on mobility have been widely used. As portable electronic devices, tablet PCs, as well as small-sized electronic devices, such as mobile phones, have been widely used recently.

Portable electronic devices include display devices capable of supporting various functions and providing users with visual information, such as images or videos. Recently, as the sizes of components for driving display devices have been reduced, the relative importance of the display devices in electronic devices has gradually increased, and a structure bendable by a certain angle from a flat state has been developed.

### SUMMARY

A display device as described above may include a structure in which a portion thereof may bend. In this case (e.g., in the case of the bendable structure), curved portions of the display device may overlap each other, thereby increasing the volume of the display device and increasing the size of a case when the display device is located on the case or the like. One or more embodiments include a display device having a reduced thickness in order to solve this problem.

Additional aspects will be set forth in part in the description which follows and, in part, will be apparent from the description, or may be learned by practice of the presented embodiments of the disclosure.

According to one or more embodiments, a display device includes a support substrate including a first portion and a second portion that are separated from each other, a substrate fixed to one surface of the second portion of the support substrate, and including a display area on the first portion of the support substrate, a peripheral area on the second portion of the support substrate, and a bending area connecting the display area to the peripheral area, and a display portion in the display area of the substrate.

The first portion of the support substrate may define an insertion groove into which the second portion of the support substrate is inserted.

The display device may further include a protective member in the insertion groove.

A portion of an edge of a plane of the first portion of the support substrate may overlap a planar shape of the display area.

At least a portion of the second portion of the support substrate may overlap the display area in a plan view.

The display device may further include a protection layer on the substrate and corresponding to the bending area.

The size of a planar shape of the first portion of the support substrate may be greater than the size of a planar shape of the second portion of the support substrate.

At least a portion of a boundary of the first portion of the support substrate may be below the display area.

At least a portion of a boundary of the second portion of the support substrate may be below the display area.

A boundary of the display area may be inside a boundary of the first portion of the support substrate in a plan view.

According to one or more embodiments, a display device includes a support substrate including a first portion and a second portion that are separated from each other, and a substrate on the support substrate, and having an area between the first portion of the support substrate and the second portion of the support substrate that is bent, wherein one surface of the second portion of the support substrate and the other surface of the second portion of the support substrate that oppose each other, are attached to the substrate.

The display device may further include an adhesive member between the other surface of the second portion of the support substrate and the substrate.

The second portion of the support substrate may be inside the first portion of the support substrate.

The substrate may include a display area including a display portion, and a peripheral area adjacent to the display area.

At least a portion of the second portion of the support substrate may overlap the display area in a plan view.

A boundary of the display area may be located on the second portion of the support substrate.

The second portion of the support substrate may be inside an insertion groove formed in the first portion of the support substrate.

The display device may further include a protective member between the second portion of the support substrate and the first portion of the support substrate.

The substrate may further include a bending portion with filler therein.

According to one or more embodiments, a display device includes a support substrate including a first portion and a second portion that are separated from each other, a substrate on the first portion and the second portion of the support substrate and including a display area, and a display portion in the display area, wherein the second portion of the support substrate is attached to the substrate, and at least a portion of the second portion of the support substrate overlaps the display area in a plan view.

The above and other aspects, features, and advantages of certain embodiments of the disclosure will be more apparent from the following description, the accompanying drawings, and claims.

### BRIEF DESCRIPTION OF THE DRAWINGS

The above and other aspects and features of embodiments of the present disclosure will be more apparent from the following description taken in conjunction with the accompanying drawings, in which:

FIG. 1 is a plan view illustrating a display device according to one or more embodiments;

FIG. 2 is a cross-sectional view of the display device of FIG. 1 taken along the line II-II′ in FIG. 1;

FIGS. 3 and 4 are circuit diagrams illustrating a display panel shown in FIG. 1;

FIG. 5 is a schematic cross-sectional view illustrating a bent state of the display device shown in FIG. 1;

FIGS. 6A and 6B are schematic rear views illustrating a lower surface of a support substrate shown in FIG. 5;

FIGS. 7A to 7E are schematic views sequentially illustrating a method of manufacturing the display device shown in FIG. 5;

FIG. 8 is a schematic cross-sectional view illustrating a portion of a display panel of a display device according to one or more embodiments;

FIG. 9 is a schematic cross-sectional view illustrating a portion of a display panel of a display device according to one or more embodiments; and

FIG. 10 is a schematic cross-sectional view illustrating a portion of a display panel of a display device according to one or more other embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, embodiments are merely described below, by referring to the figures, to explain aspects of the present disclosure. As used herein, the term “and/or” includes any and all combinations of one or more of the associated listed items. Throughout the present disclosure, the expression “at least one of a, b or c” indicates only a, only b, only c, both a and b, both a and c, both b and c, all of a, b, and c, or variations thereof.

As the present disclosure allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, the present embodiments may have different forms and should not be construed as being limited to the descriptions set forth herein.

Hereinafter, the present embodiments are described in detail with reference to the accompanying drawings. In the drawings, the same reference numerals are given to the same or corresponding elements, and repeated description thereof is omitted.

It will be understood that although terms such as “first” and “second” may be used herein to describe various components, these components should not be limited by these terms and these terms are only used to distinguish one component from another component.

Also, as used herein, the singular forms “a,” “an,” and “the” are intended to include the plural forms as well, unless the context clearly indicates otherwise.

Also, it will be understood that the terms “comprise,” “include,” and “have” used herein specify the presence of stated features or components, but do not preclude the presence or addition of one or more other features or components.

Also, it will be understood that when a layer, region, or component is referred to as being “located on” another layer, region, or component, it may be “directly” or “indirectly” located on the other layer, region, or component, that is, for example, one or more intervening layers, regions, or components may be located therebetween.

Sizes of components in the drawings may be exaggerated for convenience of description. In other words, because the sizes and thicknesses of components in the drawings are arbitrarily illustrated for convenience of description, the present disclosure is not limited thereto.

The X-axis, the Y-axis, and the Z-axis are not limited to three axes of the rectangular coordinate system and may be interpreted in a broader sense. For example, the X axis, the Y axis, and the Z axis may be perpendicular to each other, or may represent different directions that are not perpendicular to each other.

When a certain embodiment may be implemented differently, a particular process order may be performed differently from the described order. For example, two consecutively described processes may be performed substantially at the same time or performed in an order opposite to the described order.

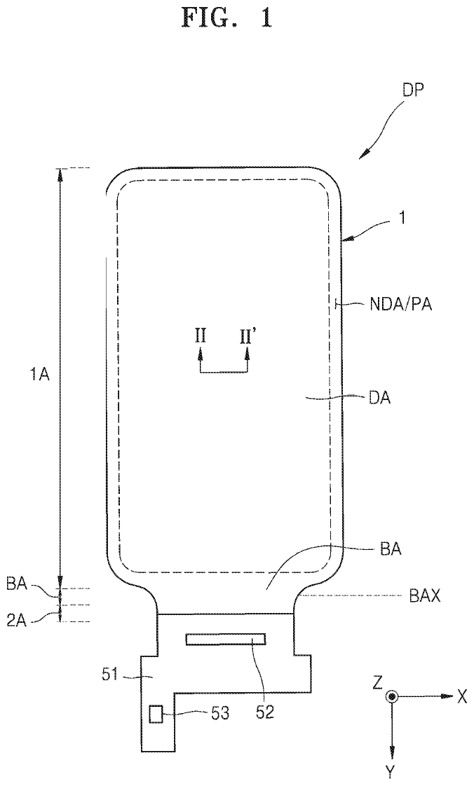

FIG. 1 is a plan view illustrating a display device DP according to one or more embodiments.

Referring to FIG. 1, the display device DP may include a display panel 1, a display circuit board 51, a display driver 52, and a touch sensor driver 53. The display panel 1 may be a light-emitting display panel including a light-emitting element. For example, the display panel 1 may include an organic light-emitting display panel using an organic light-emitting diode including an organic emission layer, a micro light-emitting diode display panel using a micro light-emitting diode, a quantum dot light-emitting display panel using a quantum dot light-emitting diode including a quantum dot emission layer, or an inorganic light-emitting display panel using an inorganic light-emitting diode including an inorganic semiconductor.

The display panel 1 may be a flexible display panel that is easily bendable, foldable, or rollable. For example, the display panel 1 may be a foldable display panel, a curved display panel having a curved display surface, a bendable display panel having a bendable region other than the display surface, a rollable display panel that is rollable and spreadable, and a stretchable display panel.

The display panel 1 may be transparent so that an object or background behind the display panel 1 may be seen from a front surface the display panel 1. Alternatively, the display panel 1 may be a reflective display panel that may reflect an object or background in front the display panel 1.

The display panel 1 may include a display area DA in which an image is displayed, and a peripheral area PA (or a non-display area NDA) arranged along an edge or periphery of the display area DA to be around (e.g., to surround) the display area DA. A separate driving circuit, a pad, etc. may be arranged in the peripheral area PA.

Also, the display panel 1 may include a first area 1A arranged in the display area DA, a bending area BA that bends around a bending axis BAX, and a second area 2A connected to the bending area BA and the display circuit board 51. In this case, the second area 2A and the bending area BA may be included in the peripheral area PA, and an image may not be displayed in the second area 2A and the bending area BA. The length of one side of the bending area BA connected to the first area 1A may be less than the length of one side of the first area 1A. That is, the width of the bending area BA in the X-axis direction of FIG. 1 may decrease from the first area 1A toward the second area 2A and may be constant in a certain area.

The display circuit board 51 may be attached to an edge of one side of the display panel 1. One side of the display circuit board 51 may be attached to an edge of one side of the display panel 1 by using an anisotropic conductive film.

The display driver 52 may be located on the display circuit board 51. The display driver 52 may receive control signals and power voltages, and may generate and output signals and voltages for driving the display panel 1. The display driver 52 may include an integrated circuit.

The display circuit board 51 may be attached to the display panel 1. In this case, the display circuit board 51 and the display panel 1 may be attached to each other by using an anisotropic conductive film. The display circuit board 51 may be a flexible printed circuit board (FPCB) that may bend or a composite printed circuit board including both a rigid printed circuit board (RPCB), which is rigid and does not easily bend, and an FPCB.

The touch sensor driver 53 may be located on the display circuit board 51. The touch sensor driver 53 may include an integrated circuit. The touch sensor driver 53 may be attached on the display circuit board 51. The touch sensor driver 53 may be electrically connected to touch electrodes of a touch electrode layer of the display panel 1 through the display circuit board 51.

The touch electrode layer of the display panel 1 may sense a touch input from a user by using at least one of various touch methods (e.g., touch sensing methods), such as a resistive method and a capacitive method. For example, when the touch electrode layer of the display panel 1 senses a touch input from the user by the capacitive method, the touch sensor driver 53 may apply driving signals to driving electrodes from among the touch electrodes, and may sense voltages, charged in mutual capacitance between the driving electrodes and sensing electrodes, by using the sensing electrodes from among the touch electrodes to determine whether there is a touch by the user. The touch by the user may include a contact touch and a proximity touch. The contact touch may denote that a finger of the user or an object, such as a stylus pen, directly contacts a cover member on a touchscreen layer. The proximity touch may denote that the finger of the user or an object, such as a stylus pen, is close to the cover member, but not in direct contact with the cover member (e.g., the finger of the user or an object, such as a stylus pen, may be hovering near the cover member, but is not in direct contact with the cover member). The touch sensor driver 53 may transmit sensor data to a main processor according to sensed voltages, and the main processor may analyze the sensor data to calculate a touch coordinate where the touch input occurs.

A power supplier for supplying driving voltages for driving pixels, a scan driver, and the display driver 52 of the display panel 1 thereto may be additionally located on the display circuit board 51. Alternatively, the power supplier may be integrated with the display driver 52, and in this case, the display driver 52 and the power supplier may be provided as one integrated circuit.

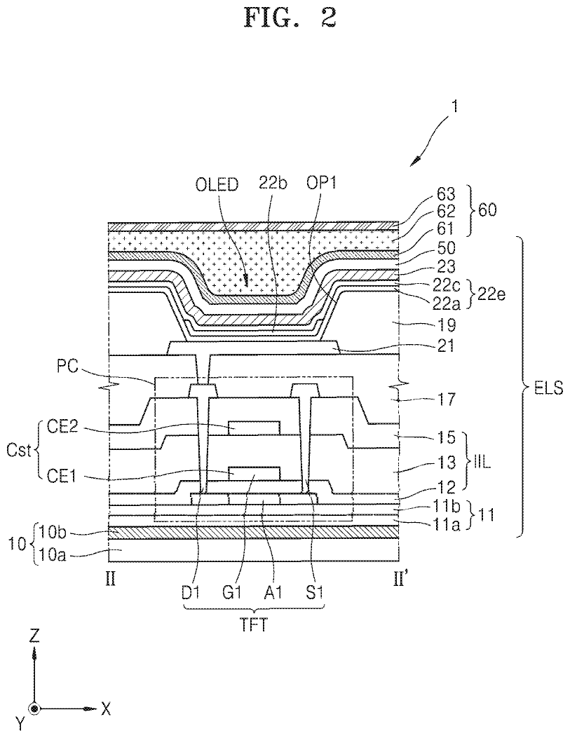

FIG. 2 is a cross-sectional view of the display device DP taken along the line II-II′ in FIG. 1.

Referring to FIG. 2, the display panel 1 may include a display portion ELS including a base substrate 10 (e.g., 10a, 10b), a buffer layer 11, a circuit layer, and a display element layer. Also, the display panel 1 may include an encapsulation member for shielding the display element layer.

The base substrate 10 may include an insulating material, such as glass, quartz, and/or polymer resin. The base substrate 10 may include a substrate 10b and a support substrate 10a. In this case, the support substrate 10a may include an insulating material, such as glass and/or quartz. The support substrate 10a may include portions separated from each other. For example, the support substrate 10a may be divided into two or three portions.

The substrate 10b may include an insulating material, such as polymer resin. In this case, the substrate 10b may be a flexible substrate that is bendable, foldable, or rollable. When the substrate 10b includes an insulating material, such as polymer resin, the substrate 10b may have a structure in which layers including organic materials are alternately stacked with layers including inorganic materials. For example, the substrate 10b may include an organic material layer including any one of polyimide, polyethylene naphthalate, polyethylene terephthalate, polyarylate, polycarbonate, polyetherimide, and polyethersulfone, and an inorganic material layer including at least one of silicon oxide, silicon oxynitride, silicon nitride, and amorphous silicon.

The buffer layer 11 may be located on the substrate 10b to reduce or block penetration of foreign matter, moisture, or external air to the display panel 1, and may provide a flat surface on the base substrate 10. The buffer layer 11 may include an inorganic material, such as an oxide or nitride, an organic material, or an organic/inorganic composite, and may have a single-layer structure or a multilayer structure including an inorganic material and an organic material. A barrier layer that blocks penetration of external air may be further included between the substrate 10b and the buffer layer 11. In some embodiments, the buffer layer 11 may include silicon oxide (SiO₂) or silicon nitride (SiNₓ). The buffer layer 11 may be provided such that a first buffer layer 11a is stacked on a second buffer layer 11b or a second buffer layer 11b is stacked on a first buffer layer 11a.

The circuit layer may be located on the buffer layer 11, and may include a pixel circuit PC, a first gate insulating layer 12, a second gate insulating layer 13, an interlayer insulating layer 15, and a planarization layer 17. The pixel circuit PC may include a thin-film transistor TFT and a storage capacitor Cst.

The thin-film transistor TFT may be located on the buffer layer 11, wherein the thin-film transistor TFT is connected to an organic light-emitting diode OLED, which is an organic light-emitting element, and drives the organic light-emitting diode OLED. The thin-film transistor TFT may include a first semiconductor layer A1, a first gate electrode G1, a first source electrode S1, and a first drain electrode D1.

The first semiconductor layer A1 may be located on the buffer layer 11 and may include polysilicon. In one or more embodiments, the first semiconductor layer A1 may include amorphous silicon. In one or more embodiments, the first semiconductor layer A1 may include an oxide of at least one material selected from the group including indium (In), gallium (Ga), stanium (Sn), zirconium (Zr), vanadium (V), hafnium (Hf), cadmium (Cd), germanium (Ge), chromium (Cr), titanium (Ti), and zinc (Zn). The first semiconductor layer A1 may include a channel region, and a source region and a drain region doped with impurities.

The first gate insulating layer 12 may be provided to cover the first semiconductor layer A1 and the buffer layer 11. The first gate insulating layer 12 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). In this case, ZnO may include zinc oxide (ZnO) and/or zinc peroxide (ZnO₂). The first gate insulating layer 12 may include a single layer or multilayer including the aforementioned inorganic insulating material.

The first gate electrode G1 may be located on the first gate insulating layer 12 and overlap the first semiconductor layer A1 in a thickness direction of the base substrate 10 (e.g., a Z-axis direction). The first gate electrode G1 may include molybdenum (Mo), aluminum (Al), copper (Cu), titanium (Ti), and the like, and may include a single layer or multiple layers. For example, the first gate electrode G1 may include a single Mo layer.

The second gate insulating layer 13 may be provided to cover the first gate electrode G1 and the first gate insulating layer 12. The second gate insulating layer 13 may include an inorganic insulating material, such as SiO₂, SiNₓ, SiON, Al₂O₃, TiO₂, Ta₂O₅, HfO₂, or ZnOₓ. In this case, ZnO may include zinc oxide (ZnO) and/or zinc peroxide (ZnO₂). The second gate insulating layer 13 may include a single layer or multilayer including the aforementioned inorganic insulating material.

A first upper electrode CE2 of the storage capacitor Cst may be located on the second gate insulating layer 13.

In the display area DA, the first upper electrode CE2 may overlap the first gate electrode G1 thereunder in a thickness direction of the base substrate 10 (e.g., a Z-axis direction). The first gate electrode G1 and the first upper electrode CE2 overlapping each other with the second gate insulating layer 13 therebetween may form the storage capacitor Cst. The first gate electrode G1 may be a first lower electrode CE1 of the storage capacitor Cst.

The first upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may include a single layer or multilayer including the aforementioned material.

The interlayer insulating layer 15 may be formed to cover the first upper electrode CE2 and the second gate insulating layer 13. The interlayer insulating layer 15 may include SiO₂, SiNₓ, SiON, Al₂O₃, TiO₂, Ta₂O₅, HfO₂, ZnOₓ, or the like. In this case, ZnOₓ may include zinc oxide (ZnO) and/or zinc peroxide (ZnO₂). The interlayer insulating layer 15 may include a single layer or multilayer including the aforementioned inorganic insulating material.

The first source electrode S1 and the first drain electrode D1 may be located on the interlayer insulating layer 15. Each of the first source electrode S1 and the first drain electrode D1 may include a conductive material including Mo, Al, Cu, Ti, or the like, and may be formed as a multilayer or single layer including the aforementioned material. For example, the first source electrode S1 and the first drain electrode D1 may have a multilayer structure of Ti/Al/Ti.

The planarization layer 17 may be arranged to cover the first source electrode S1 and the first drain electrode D1. The planarization layer 17 may have a flat upper surface so that a pixel electrode 21 located thereon may be formed flat.

The planarization layer 17 may include an organic material or an inorganic material, and may have a single-layer structure or a multilayer structure. The planarization layer 17 may include a commercial polymer, such as benzocyclobutene (BCB), polyimide, hexamethyldisiloxane (HMDSO), polymethyl methacrylate (PMMA), or polystyrene, a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a blend thereof, or the like. The planarization layer 17 may include an inorganic insulating material, such as SiO₂, SiNₓ, SiON, Al₂O₃, TiO₂, Ta₂O₅, HfO₂, or ZnOₓ. In this case, ZnOₓ may include zinc oxide (ZnO) and/or zinc peroxide (ZnO₂). When forming the planarization layer 17, chemical mechanical polishing may be performed on the upper surface of a layer to provide a flat upper surface after the layer is formed.

The pixel electrode 21 may be on the planarization layer 17. The planarization layer 17 may have a via hole exposing one of the first source electrode S1 and the first drain electrode D1 of the thin-film transistor TFT, and the pixel electrode 21 may contact the first source electrode S1 or the first drain electrode D1 through the via hole and may be electrically connected to the thin-film transistor TFT.

The pixel electrode 21 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). The pixel electrode 21 may include a reflective layer including Ag, Mg, Al, Pt, Pd, Au, Ni, Nd, Ir, Cr, or a compound thereof. For example, the pixel electrode 21 may have a structure including layers including ITO, IZO, ZnO, or In₂O₃ above or below the reflective layer. In this case, the pixel electrode 21 may have a stacked structure of ITO/Ag/ITO.

A pixel-defining layer 19 on the planarization layer 17 may cover the edge of the pixel electrode 21 and may have a first opening OP1 exposing a central portion of the pixel electrode 21. The size and shape of an emission area of the organic light-emitting diode OLED, that is, the size and shape of a sub-pixel, are defined by the first opening OP1.

The pixel-defining layer 19 may increase the distance between the edge of the pixel electrode 21 and an opposite electrode 23 above the pixel electrode 21, thereby preventing the occurrence of arcs at the edge of the pixel electrode 21. The pixel-defining layer 19 may include an organic insulating material, such as polyimide, polyamide, acrylic resin, BCB, HMDSO, or phenol resin, and may be formed by spin coating or the like.

An emission layer 22b formed to correspond to the pixel electrodes 21 may be arranged inside the first opening OP1 of the pixel-defining layer 19. The emission layer 22b may include a high molecular weight material or a low molecular weight material and may emit red, green, blue, or white light.

An organic functional layer 22e may be located above and/or below the emission layer 22b. The organic functional layer 22e may include a first functional layer 22a and/or a second functional layer 22c. The first functional layer 22a or the second functional layer 22c may be omitted.

The first functional layer 22a may be located under the emission layer 22b. The first functional layer 22a may include a single layer or multilayer including an organic material. The first functional layer 22a may be a hole transport layer (HTL) having a single-layer structure. Alternatively, the first functional layer 22a may include a hole injection layer (HIL) and an HTL. The first functional layer 22a may be integrally formed to correspond to organic light-emitting diodes OLED included in the display area DA.

The second functional layer 22c may be located on the emission layer 22b. The second functional layer 22c may include a single layer or multilayer including an organic material. The second functional layer 22c may include an electron transport layer (ETL) and/or an electron injection layer (EIL). The second functional layer 22c may be integrally formed to correspond to the organic light-emitting diodes OLED included in the display area DA.

The opposite electrode 23 may be located on the second functional layer 22c. The opposite electrode 23 may include a conductive material having a low work function. For example, the opposite electrode 23 may include a transparent or a semi-transparent layer including Ag, Mg, Al, Pt, Pd, Au, Ni, Nd, Ir, Cr, Li, Ca, or an alloy thereof. Alternatively, the opposite electrode 23 may further include a layer including ITO, IZO, ZnO, or In₂O₃ on the semi-transparent layer including the aforementioned material. The opposite electrode 23 may be integrally formed to correspond to the organic light-emitting diodes OLED included in the display area DA.

Layers from the pixel electrode 21 to the opposite electrode 23, which are formed in the display area DA, may form the organic light-emitting diode OLED.

An upper layer 50 including an organic material may be formed on the opposite electrode 23. The upper layer 50 may be a layer provided to protect the opposite electrode 23 and increase light extraction efficiency. The upper layer 50 may include an organic material having a higher refractive index than the opposite electrode 23. Alternatively, the upper layer 50 may be provided by stacking layers having different refractive indices. For example, the upper layer 50 may be provided by sequentially stacking a high refractive index layer, a low refractive index layer, and a high refractive index layer. In this case, the refractive index of the high refractive index layer may be 1.7 or more, and the refractive index of the low refractive index layer may be 1.3 or less.

The upper layer 50 may additionally include LiF. Alternatively, the upper layer 50 may additionally include an inorganic insulating material, such as SiO₂ or SiNₓ. The upper layer 50 may be omitted if necessary. However, hereinafter, for convenience of description, a case, in which the upper layer 50 is located on the opposite electrode 23, will be described in detail.

In one or more embodiments, in the display device DP, the encapsulation member may shield the upper layer 50. In this case, the encapsulation member may include a thin-film encapsulation layer 60 for shielding the upper layer 50.

The thin-film encapsulation layer 60 may be arranged to directly contact the upper layer 50. In this case, the thin-film encapsulation layer 60 may cover portions of the display area DA and the peripheral area PA to prevent penetration of external moisture and oxygen. The thin-film encapsulation layer 60 may include at least one organic encapsulation layer and at least one inorganic encapsulation layer. Hereinafter, for convenience of description, a case, in which the thin-film encapsulation layer 60 includes a first inorganic encapsulation layer 61, an organic encapsulation layer 62, and a second inorganic encapsulation layer 63 sequentially stacked on the upper surface of the upper layer 50, will be described in detail.

In the above case, the first inorganic encapsulation layer 61 may cover the upper layer 50 and may include silicon oxide, silicon nitride, and/or silicon oxynitride. Because the first inorganic encapsulation layer 61 is formed along a structure thereunder, the upper surface of the first inorganic encapsulation layer 61 may not be flat. The organic encapsulation layer 62 may cover the first inorganic encapsulation layer 61, and unlike the first inorganic encapsulation layer 61, the upper surface of the organic encapsulation layer 62 may be substantially flat. Specifically, the organic encapsulation layer 62 may have a substantially flat upper surface in a portion corresponding to the display area DA. The organic encapsulation layer 62 may include one or more materials selected from the group consisting of polyethylene terephthalate, polyethylene naphthalate, polycarbonate, polyimide, polyethylene sulfonate, polyoxymethylene, polyarylate, and hexamethyldisiloxane. The second inorganic encapsulation layer 63 may cover the organic encapsulation layer 62 and may include silicon oxide, silicon nitride, and/or silicon oxynitride.

A touch electrode layer may be located on the thin-film encapsulation layer 60.

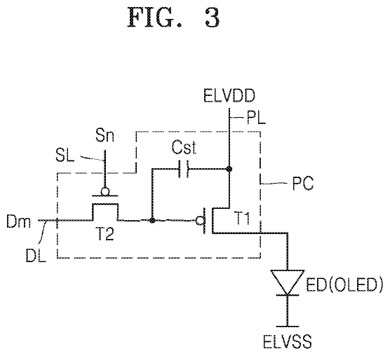

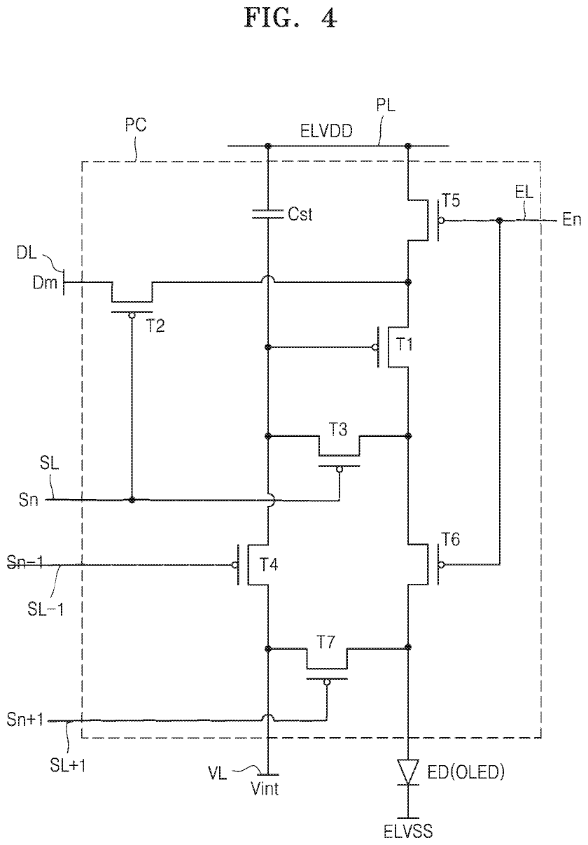

FIGS. 3 and 4 are circuit diagrams illustrating the display panel 1 shown in FIG. 1.

Referring to FIGS. 3 and 4, a pixel circuit PC may be connected to a light-emitting element ED to realize light emission of sub-pixels. In this case, the light-emitting element ED may be the organic light-emitting diode OLED shown in FIG. 2. The pixel circuit PC may include a driving thin-film transistor T1, a switching thin-film transistor T2, and a storage capacitor Cst. The switching thin-film transistor T2 may be connected to a scan line SL and a data line DL, and the storage capacitor Cst, and may be configured to transmit, to the driving thin-film transistor T1, a data signal Dm input through the data line DL according to a scan signal Sn input through the scan line SL. For example, one electrode of the switching thin-film transistor T2 may be connected to the data line DL, an other electrode of the switching thin-film transistor T2 may be connected to one electrode of the storage capacitor Cst, and a gate electrode of the switching thin-film transistor T2 may be connected to the scan line SL.

The storage capacitor Cst may be connected to the switching thin-film transistor T2 and a driving voltage line PL, and may be configured to store a voltage corresponding to a difference between a voltage received from the switching thin-film transistor T2 and a driving voltage ELVDD supplied to the driving voltage line PL. For example, one electrode of the storage capacitor Cst may be connected to the driving voltage line PL and an other electrode of the storage capacitor Cst may be connected to the other electrode of the switching thin-film transistor T2 and a gate electrode of the driving thin-film transistor T1.

The driving thin-film transistor T1 may be connected to the driving voltage line PL, the light-emitting element ED, and the storage capacitor Cst, and may configured to control a driving current flowing from the driving voltage line PL to the light-emitting element ED, in response to a voltage value stored in the storage capacitor Cst. For example, one electrode of the driving thin-film transistor T1 may be connected to the driving voltage line PL, one other electrode of the driving thin-film transistor T1 may be connected to the light-emitting element ED, and the gate electrode of the driving thin-film transistor T1 may be connected to the storage capacitor Cst. The light-emitting element ED may emit light having a certain luminance according to the driving current. The light-emitting element ED may be connected between the other electrode of the driving thin-film transistor T1 and a common voltage line providing a common voltage ELVSS.

Although FIG. 3 illustrates a case in which the pixel circuit PC includes two thin-film transistors and one storage capacitor, the present disclosure is not limited thereto.

Referring to FIG. 4, the pixel circuit PC may include a driving thin-film transistor T1, a switching thin-film transistor T2, a compensation thin-film transistor T3, a first initialization thin-film transistor T4, an operation control thin-film transistor T5, an emission control thin-film transistor T6, and a second initialization thin-film transistor T7.

Although FIG. 4 illustrates a case in which signal lines (i.e., a scan line SL, a previous scan line SL−1, a subsequent scan line SL+1, an emission control line EL, and a data line DL), an initialization voltage line VL, and a driving voltage line PL are provided for each pixel circuit PC, the present disclosure is not limited thereto. In one or more embodiments, at least one of the signal lines (i.e., the scan line SL, the previous scan line SL−1, the subsequent scan line SL+1, the emission control line EL, and the data line DL), and/or the initialization voltage line VL may be shared by neighboring pixel circuits.

The drain electrode of the driving thin-film transistor T1 may be electrically connected to the light-emitting element ED via the emission control thin-film transistor T6. The driving thin-film transistor T1 may be configured to receive the data signal Dm according to a switching operation of the switching thin-film transistor T2 and supply a driving current to the light-emitting element ED.

The gate electrode of the switching thin-film transistor T2 may be connected to the scan line SL, and the source electrode of the switching thin-film transistor T2 may be connected to the data line DL. The drain electrode of the switching thin-film transistor T2 may be connected to the source electrode of the driving thin-film transistor T1 and may be connected to the driving voltage line PL via the operation control thin-film transistor T5.

The switching thin-film transistor T2 may be configured to be turned on according to the scan signal Sn received through the scan line SL and perform a switching operation for transmitting the data signal Dm, transmitted through the data line DL, to the source electrode of the driving thin-film transistor T1.

The gate electrode of the compensation thin-film transistor T3 may be connected to the scan line SL. The source electrode of the compensation thin-film transistor T3 may be connected to the drain electrode of the driving thin-film transistor T1 and may be connected to a pixel electrode of the light-emitting element ED via the emission control thin-film transistor T6. The drain electrode of the compensation thin-film transistor T3 may be connected to one electrode of the storage capacitor Cst, the source electrode of the first initialization thin-film transistor T4, and the gate electrode of the driving thin-film transistor T1. The compensation thin-film transistor T3 may be turned on according to the scan signal Sn received through the scan line SL and connect the gate electrode and the drain electrode of the driving thin-film transistor T1 to each other, and thus, the driving thin-film transistor T1 may be diode-connected.

The gate electrode of the first initialization thin-film transistor T4 may be connected to the previous scan line SL−1. The drain electrode of the first initialization thin-film transistor T4 may be connected to the initialization voltage line VL. The source electrode of the first initialization thin-film transistor T4 may be connected to one electrode of the storage capacitor Cst, the drain electrode of the compensation thin-film transistor T3, and the gate electrode of the driving thin-film transistor T1. The first initialization thin-film transistor T4 may be configured to be turned on according a previous scan signal Sn−1 received through the previous scan line SL−1 and transmit an initialization voltage Vint to the gate electrode of the driving thin-film transistor T1 to perform an initialization operation for initializing the voltage of the gate electrode of the driving thin-film transistor T1.

The gate electrode of the operation control thin-film transistor T5 may be connected to the emission control line EL. The source electrode of the operation control thin-film transistor T5 may be connected to the driving voltage line PL. The drain electrode of the operation control thin-film transistor T5 may be connected to the source electrode of the driving thin-film transistor T1 and the drain electrode of the switching thin-film transistor T2.

The gate electrode of the emission control thin-film transistor T6 may be connected to the emission control line EL. The source electrode of the emission control thin-film transistor T6 may be connected to the drain electrode of the driving thin-film transistor T1 and the source electrode of the compensation thin-film transistor T3. The drain electrode of the emission control thin-film transistor T6 may be electrically connected to the pixel electrode of the light-emitting element ED. The operation control thin-film transistor T5 and the emission control thin-film transistor T6 may be concurrently (e.g., simultaneously) turned on according to an emission control signal En received through the emission control line EL, and thus, the driving voltage ELVDD may be transmitted to the light-emitting element ED and a driving current may flow through the light-emitting element ED.

The gate electrode of the second initialization thin-film transistor T7 may be connected to the subsequent scan line SL+1. The source electrode of the second initialization thin-film transistor T7 may be connected to the pixel electrode of the light-emitting element ED. The drain electrode of the second initialization thin-film transistor T7 may be connected to the initialization voltage line VL. The second initialization thin-film transistor T7 may be configured to be turned on according to a subsequent scan signal Sn+1, received through the subsequent scan line SL+1, and initialize the pixel electrode of the light-emitting element ED.

Although FIG. 4 illustrates a case in which the first initialization thin-film transistor T4 and the second initialization thin-film transistor T7 are respectively connected to the previous scan line SL−1 and the subsequent scan line SL+1, the present disclosure is not limited thereto. In one or more embodiments, both the first initialization thin-film transistor T4 and the second initialization thin-film transistor T7 may be connected to the previous scan line SL−1 and driven according to the previous scan signal Sn−1.

One electrode of the storage capacitor Cst may be connected to the driving voltage line PL. The other electrode of the storage capacitor Cst may be connected to the gate electrode of the driving thin-film transistor T1, the drain electrode of the compensation thin-film transistor T3, and the source electrode of the first initialization thin-film transistor T4.

An opposite electrode (e.g., a cathode) of the light-emitting element ED may receive a common voltage ELVSS. The light-emitting element ED may receive a driving current from the driving thin-film transistor T1 and emit light.

The pixel circuit PC is not limited to the numbers of thin-film transistors and storage capacitors and the circuit design described with reference to FIGS. 3 and 4, and the numbers of thin-film transistors and storage capacitors and the circuit design may be variously changed.

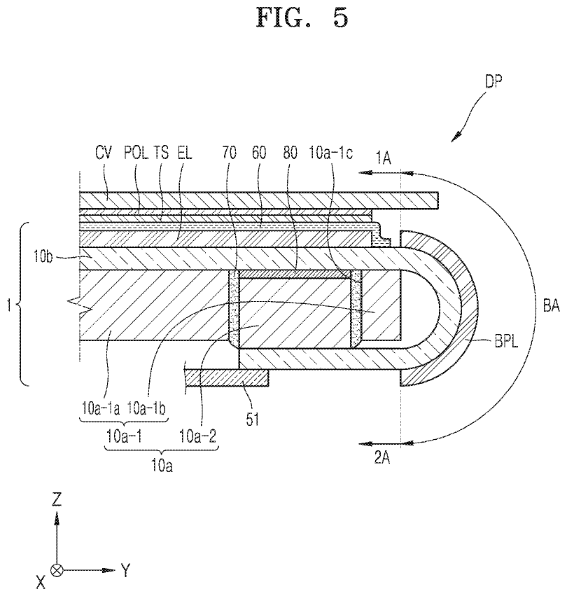

FIG. 5 is a schematic cross-sectional view illustrating a bent state of the display device DP shown in FIG. 1.

Referring to FIG. 5, the display device DP may include a display panel 1, an optical function layer POL, and a cover member CV. In this case, the display panel 1 may include a touch electrode layer TS located on a thin-film encapsulation layer 60. The touch electrode layer TS may include an electrode pattern, and may be located on the thin-film encapsulation layer 60 in the form of a panel or may have a form in which an electrode pattern is stacked on the thin-film encapsulation layer 60. The touch electrode layer TS may acquire coordinate information according to an external input, for example, a touch event.

The optical functional layer POL may reduce the reflectance of light (e.g., external light) incident from the outside toward the display device DP, and/or may improve the color purity of light emitted from the display device DP. In one or more embodiments, the optical functional layer POL may include a retarder and a polarizer. The retarder may be of a film type or a liquid crystal coating type, and may include a λ/2 retarder and/or a λ/4 retarder (e.g., A may be a wavelength of the incident light). The polarizer may also be of a film type or a liquid crystal coating type. The film type may include a stretched synthetic resin film, and the liquid crystal coating type may include liquid crystals arranged in a certain arrangement. The retarder and the polarizer may each further include a protective film.

In one or more embodiments, the optical functional layer POL may include a black matrix and color filters. The color filters may be arranged by considering the color of light emitted from each of the pixels of the display panel 1. Each of the color filters may include a red, green, or blue pigment or dye. Alternatively, each of the color filters may further include quantum dots in addition to the aforementioned pigments or dyes. Alternatively, some of the color filters may not include the aforementioned pigment or dye, and may include particles (e.g., scatterers), such as titanium oxide.

In one or more embodiments, the optical functional layer POL may include a destructive interference structure. The destructive interference structure may include a first reflective layer and a second reflective layer, located on different layers. First reflected light and second reflected light respectively reflected from the first reflective layer and the second reflective layer may destructively interfere, and thus, external light reflectance may be reduced.

An adhesive member may be arranged between the touch electrode layer TS and the optical function layer POL. The adhesive member may be a pressure sensitive adhesive (PSA).

The cover member CV may include ultra-thin glass (UTG) or colorless polyimide (CPI). In this case, the optical functional layer POL may be located on the cover member CV or under the cover member CV. Hereinafter, for convenience of description, a case, in which the optical function layer POL is located under the cover member CV, will be described in detail.

A portion of the display panel 1 may bend to overlap another portion of the display panel 1. For example, in the display panel 1, a portion of a substrate 10b located in a bending area BA may bend. In this case, portions of the substrate 10b respectively located in a first area 1A, the bending area BA, and a second area 2A may be formed integrally with each other.

A support substrate 10a located under the substrate 10b may include a first support substrate 10a-1 and a second support substrate 10a-2, located to be spaced from each other. In this case, an insertion groove 10a-1c may be formed in the first support substrate 10a-1. In this case, the second support substrate 10a-2 may be inserted into the insertion groove 10a-1c.

Specifically, when the display panel 1 bends, an adhesive member 80 may be located on the second support substrate 10a-2.

The substrate 10b may bend in the bending area BA. In this case, the first support substrate 10a-1 may protect the lower surface of the substrate 10b, and thus may have its own rigidity.

Although embodiments of the disclosure show a case in which the substrate 10b bends about a bending axis so that at least a portion of the lower surface of the substrate 10b in the first area 1A opposes at least a portion of the lower surface of the substrate 10b in the second area 2A, the present disclosure is not limited thereto. For example, the curvature of the bending area BA may be less than that shown in the drawings, or the bending area BA may be narrow even though there is no significant change in the curvature of the bending area BA, and thus, the lower surface of the substrate 10b in the second area 2A may not face the lower surface of the substrate 10b in the first area 1A. That is, various modifications may be made.

The first support substrate 10a-1 and the second support substrate 10a-2, located on one surface of the substrate 10b bent as described above, may oppose each other. In this case, the second support substrate 10a-2 may be inserted into the insertion groove 10a-1c formed in the first support substrate 10a-1.

In the above case, the display area DA shown in FIG. 1 may be located on the first support substrate 10a-1. In this case, in a plan view, the edge (or boundary) of the display area DA may be arranged inside the edge (or boundary) of the first support substrate 10a-1. In a plan view, the size of the planar shape of the first support substrate 10a-1 may be greater than the size of the planar shape of the second support substrate 10a-2.

In this case, in a plan view, at least a portion of the second support substrate 10a-2 may be arranged to overlap the display area DA shown in FIG. 1. For example, in a plan view, at least a portion of the second support substrate 10a-2 may be arranged in the display area DA. In this case, in a plan view, at least a portion of the edge (or boundary) of the second support substrate 10a-2 may be arranged inside the edge (or boundary) of the display area DA.

In the above case, an adhesive member 80 may be located on one surface of the second support substrate 10a-2, and the adhesive member 80 may fix the second support substrate 10a-2 to the substrate 10b. In this case, one surface of the second support substrate 10a-2 may be fixed to the substrate 10b through the adhesive member 80, and the other surface of the second support substrate 10a-2 may be directly fixed to the substrate 10b without a separate adhesive member.

In the above case, a protective member 70 may be arranged inside the insertion groove 10a-1c. The protective member 70 may include polymer resin, such as polyurethane, polycarbonate, polypropylene, or polyethylene, or may include a material having elasticity, such as rubber, a urethane-based material, or a sponge formed by foam-molding an acrylic-based material. In the above case, the protective member 70 may be arranged inside the insertion groove 10a-1c in the form of a resin and cured.

The protective member 70 may be arranged inside the insertion groove 10a-1c and prevent the first support substrate 10a-1 and the second support substrate 10a-2 from colliding with each other. In addition, the protective member 70 may reduce the visibility of the insertion groove 10a-1c from the outside of the display device DP.

The display panel 1 may include a bending protection layer BPL arranged in the bending area BA. In this case, the bending protection layer BPL may be located in the bending area BA of the substrate 10b and prevent the substrate 10b from being damaged when the substrate 10b bends. The bending protection layer BPL may include polymer resin, such as polyethylene terephthalate (PET) or polyimide (PI).

Accordingly, the thickness of the display device DP in a height direction thereof may be reduced. In addition, in the display device DP, visibility of the edge of the insertion groove 10a-1c, the edge of the first support substrate 10a-1, and/or the edge of the second support substrate 10a-2, located under the display area DA, may be reduced through the protective member 70.

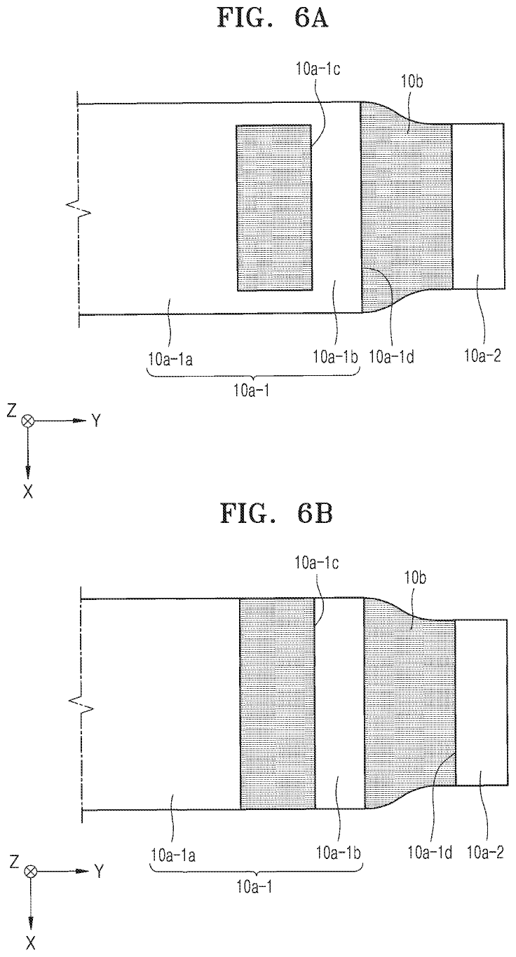

FIGS. 6A and 6B are schematic rear views illustrating a lower surface of the support substrate 10a shown in FIG. 5.

Referring to FIGS. 6A and 6B, the support substrate 10a may include a first support substrate 10a-1 and a second support substrate 10a-2. The first support substrate 10a-1 and the second support substrate 10a-2 may be separated from each other based on the bending area BA of the substrate 10b. In this case, a separate opening area 10a-1d in which the support substrate 10a is not located may be arranged in the bending area BA of the substrate 10b. The lower surface of the substrate 10b may be exposed to the outside through the opening area 10a-1d.

In the above case, an insertion groove 10a-1c may be arranged in the first support substrate 10a-1. The insertion groove 10a-1c may have various shapes.

In one or more embodiments, as shown in FIG. 6A, the insertion groove 10a-1c may be located inside the first support substrate 10a-1. In this case, the first support substrate 10a-1 may be divided into a first portion 10a-1a and a second portion 10a-1b based on the insertion groove 10a-1c. In this case, the first portion 10a-1a and the second portion 10a-1b may be connected to each other. In a plan view, the size of the planar shape of the insertion grooves 10a-1c may be greater than the size of the planar shape of the second support substrate 10a-2, and thus, interference may not occur when the second support substrate 10a-2 is inserted into the insertion grooves 10a-1c. In this case, the insertion groove 10a-1c may not divide the first support substrate 10a-1 into a plurality of pieces.

In one or more embodiments, as shown in FIG. 6B, the insertion groove 10a-1c may divide the first support substrate 10a-1 into two distinct regions. In this case, a portion of the first support substrate 10a-1 may be completely removed in one direction. That is, the first portion 10a-1a and the second portion 10a-1b may be separated from each other based on the insertion groove 10a-1c and fixed to the substrate 10b. The width of the insertion groove 10a-1c (e.g., measured in a Y-axis direction of FIG. 6B) may be greater than the width of the second support substrate 10a-2 (e.g., measured in the Y-axis direction of FIG. 6B). Accordingly, the second support substrate 10a-2 may be completely inserted into the first support substrate 10a-1.

The planar shape of the insertion grooves 10a-1c is not limited to a rectangular shape as shown in FIGS. 6A and 6B. For example, the planar shape of the insertion grooves 10a-1c may be various, such as polygonal, oval, or circular shape. In this case, the size of the planar shape of the insertion groove 10a-1c may be greater than the size of the planar shape of the second support substrate 10a-2 so that the second support substrate 10a-2 is completely inserted into the insertion groove 10a-1c.

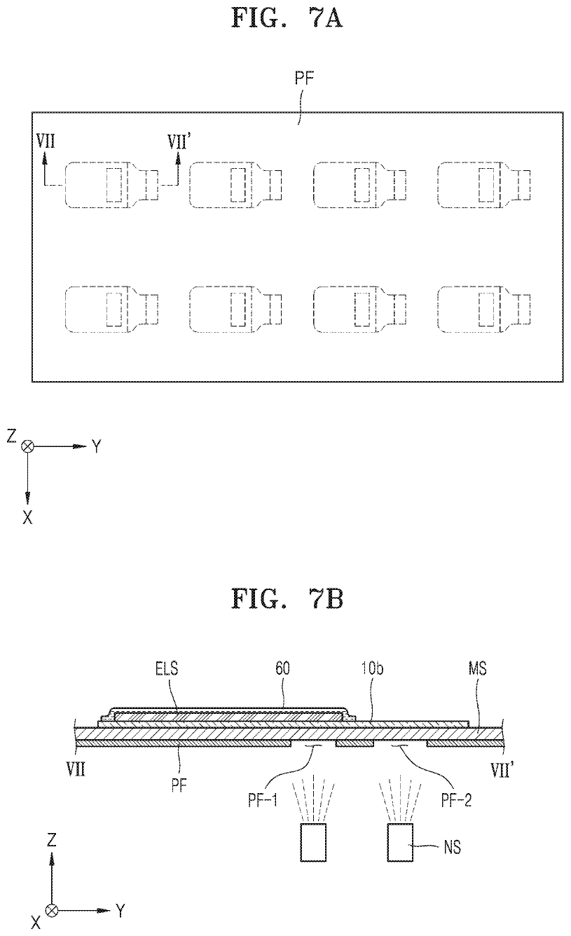

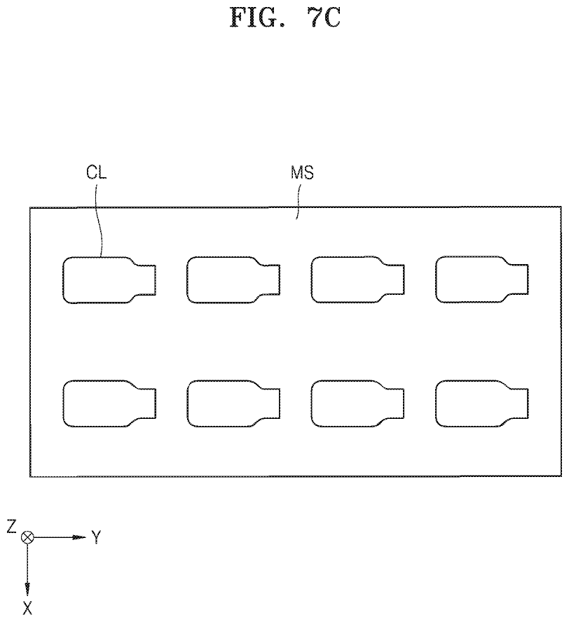

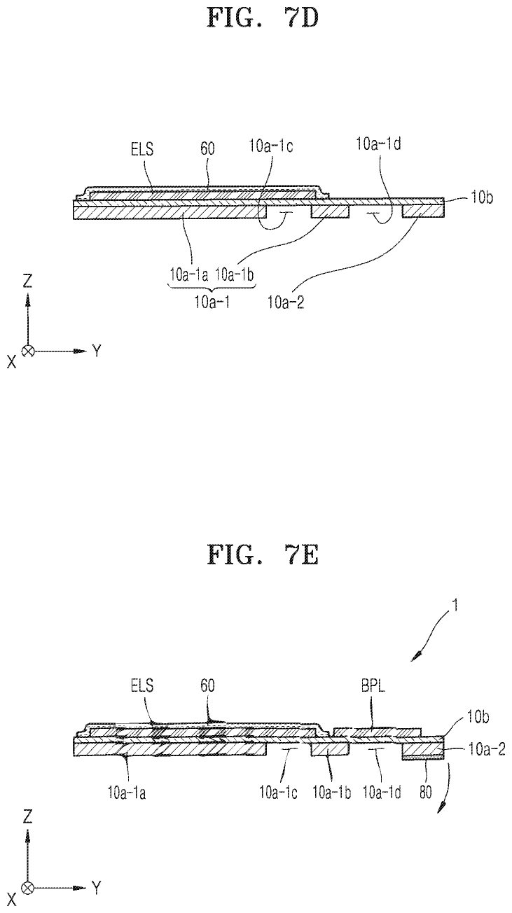

FIGS. 7A to 7E are schematic views sequentially illustrating a method of manufacturing the display device DP shown in FIG. 5.

FIG. 7B is a cross-sectional view taken along the line VII-VII′ in FIG. 7A. Referring to FIGS. 7A-7B, after a base substrate MS is prepared, the substrate 10b, the display portion ELS, and the thin-film encapsulation layer 60, described above, may be formed on the base substrate MS. In this case, the base substrate MS may include the same material as the support substrate 10a, and at least one substrate 10b may be located on the base substrate MS. In one or more embodiments, when there is only one substrate 10b, the substrate 10b may be entirely located on the base substrate MS. In this case, at least one display portion ELS may be located on the substrate 10b, and when there are a plurality of display portions ELS, the plurality of display portions ELS may be arranged to be spaced from each other on the substrate 10b. In one or more embodiments, when there are a plurality of substrates 10b, the plurality of substrates 10b may be arranged to be spaced from each other. In this case, there may be a plurality of display portions ELS, and the display portions ELS may be respectively located on the substrates 10b. Hereinafter, for convenience of description, a case, in which a plurality of substrates 10b are located on the base substrate MS and each display portion ELS and each thin-film encapsulation layer 60 are located on a substrate 10b, will be described in detail.

A protective film PF may be attached to one surface of the base substrate MS on which the substrate 10b is not located. In this case, the protective film PF may have heat resistance and chemical resistance. In the above case, a portion of the protective film PF may be removed, and a first protective film opening PF-1 and a second protective film opening PF-2 may be formed in a portion from which the protective film PF is removed. Referring to FIG. 7B, an etching solution may be sprayed, through a nozzle NS, to a portion of the protective film PF, in which the first protective film opening PF-1 and the second protective film opening PF-2 are formed. The etching solution may reach the base substrate MS exposed through the first protective film opening PF-1 and the second protective film opening PF-2 and etch the base substrate MS. Accordingly, the insertion grooves 10a-1c and the opening area 10a-1d may each be formed in a portion of the base substrate MS located under the substrate 10b.

Referring to FIG. 7C, the base substrate MS may be separated into a plurality of pieces through a cutting line CL. In this case, a method of separating the base substrate MS through the cutting line CL may be various. In one or more embodiments, the base substrate MS may be separated by irradiating a laser to the base substrate MS along the cutting line CL. In one or more embodiments, it is also possible to separate the base substrate MS into a plurality of pieces along the cutting line CL through etching after attaching a separate protective film to the inside of the cutting line CL of the base substrate MS. In this case, the method of separating the base substrate MS may be performed separately from the process described with reference to FIG. 7B or may be performed concurrently (e.g., simultaneously) with the process.

Referring to FIG. 7D, when the base substrate MS is separated along the cutting line CL, the base substrate MS may be divided into a plurality of pieces and form one display panel 1. In this case, the display panel 1 may include the substrate 10b, and a first support substrate 10a-1 having an insertion groove 10a-1c formed therein and a second support substrate 10a-2 separated from the first support substrate 10a-1 by an opening area 10a-1d may be located under the substrate 10b.

Referring to FIG. 7E, the adhesive member 80 may be located on the second support substrate 10a-2. Then, by bending a portion of the substrate 10b on which the second support substrate 10a-2 is located, the second support substrate 10a-2 may be inserted into the insertion groove 10a-1c to thereby attach the adhesive member 80 to the substrate 10b. In this case, the protective member 70 may be pre-filled in the insertion groove 10a-1c before the second support substrate 10a-2 is inserted into the insertion groove 10a-1c, or may be filled in the insertion groove 10a-1c after the second support substrate 10a-2 is inserted into the insertion groove 10a-1c.

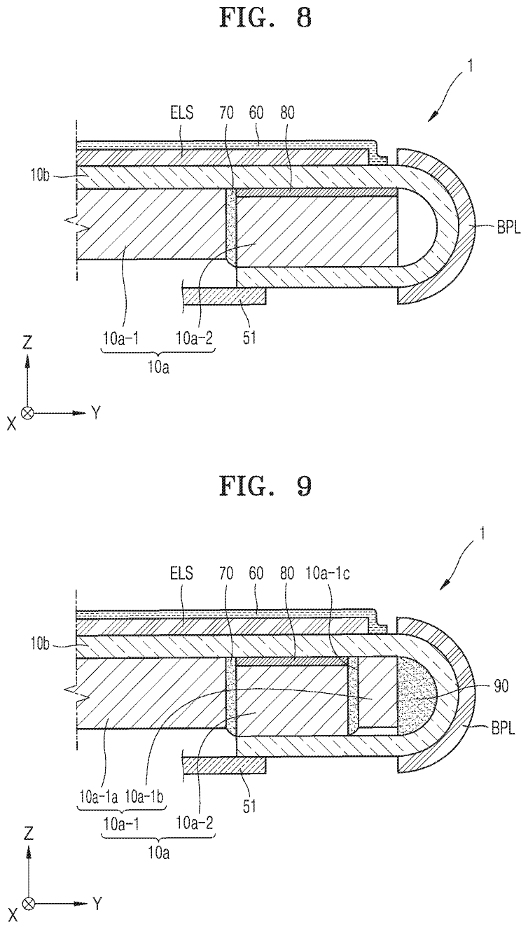

FIG. 8 is a schematic cross-sectional view illustrating a portion of a display panel 1 of a display device according to one or more embodiments.

Referring to FIG. 8, the display panel 1 may include a support substrate 10a, a substrate 10b, a display portion ELS, and a thin-film encapsulation layer 60. Also, the display panel 1 may include a bending protection layer BPL arranged in a bending area of the substrate 10b.

The support substrate 10a may include a first support substrate 10a-1 and a second support substrate 10a-2 that are separated from each other. In this case, the first support substrate 10a-1 and the second support substrate 10a-2 may be arranged to be separated from each other based on the opening area 10a-1d. In this case, a portion of the edge of the first support substrate 10a-1 may be located inside the display area DA shown in FIG. 1. In this case, in a plan view, the size of the planar shape of the first support substrate 10a-1 may be less than the size of the planar shape of the display area DA. In this case, a portion of the edge (or boundary) of the planar shape of the first support substrate 10a-1 may be located under the substrate 10b on which the display area DA is located.

In the above case, when the substrate 10b bends, the second support substrate 10a-2 may be arranged in the opening area 10a-1d (e.g., see FIGS. 6A-6B). In this case, the adhesive member 80 may be located on one surface of the second support substrate 10a-2, and the adhesive member 80 may be attached to the substrate 10b. The second support substrate 10a-2 may be located under the substrate 10b on which the display area DA is located. In this case, at least a portion of the second support substrate 10a-2 may be arranged to overlap the display area DA in a plan view. In particular, a portion of the edge (or boundary) of the display area DA may overlap the second support substrate 10a-2 in a plan view. Accordingly, a portion of the substrate 10b on which the display area DA is located may be supported through the second support substrate 10a-2, and thus, the display area DA may be maintained flat.

In the one or more embodiments corresponding to FIG. 8, the protective member 70 may be located around the second support substrate 10a-2. In this case, the protective member 70 may be located on a bent portion of the substrate 10b in addition to between the second support substrate 10a-2 and the first support substrate 10a-1. That is, in one or more embodiments, the protective member 70 may completely fill a space between the second support substrate 10a-2 and the bent portion of the substrate 10b.

In the one or more embodiments corresponding to FIG. 8, the protective member 70 may be arranged to overlap an edge portion of the display area DA in a plan view. Accordingly, the visibility of the edge of the second support substrate 10a-2 or the edge of the first support substrate 10a-1 may be reduced.

FIG. 9 is a schematic cross-sectional view illustrating a portion of a display panel 1 of a display device according to one or more embodiments.

Referring to FIG. 9, the display panel 1 may include a support substrate 10a, a substrate 10b, a display portion ELS, and a thin-film encapsulation layer 60. Also, the display panel 1 may include a bending protection layer BPL arranged in a bending area of the substrate 10b. In this case, the support substrate 10a may include a first support substrate 10a-1 having an insertion groove 10a-1c, and a second support substrate 10a-2 separated from the first support substrate 10a-1 by an opening area 10a-1d (e.g., see FIGS. 6A-6B). In this case, a method in which the second support substrate 10a-2 is attached to the substrate 10b is the same as or similar to that described above, and thus, a detailed description thereof is omitted.

The display panel 1 may include a filler 90 arranged in a bending area of the substrate 10b. In this case, the filler 90 may include an elastic material, and may maintain the bending of the substrate 10b when the substrate 10b bends. In addition, the filler 90 may prevent damage to the bending area of the substrate 10b by absorbing an impact when an external force is applied to the bending area.

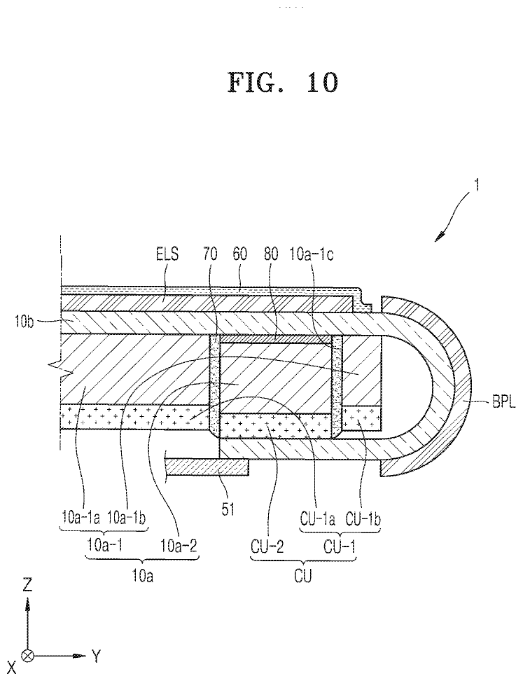

In the one or more embodiments corresponding to FIG. 9, the second support substrate 10a-2 may be fixed to the substrate 10b, as shown in FIG. 8. FIG. 10 is a schematic cross-sectional view illustrating a portion of a display panel 1 of a display device according to one or more other embodiments.

Referring to FIG. 10, the display panel 1 may include a support substrate 10a, a substrate 10b, a display portion ELS, and a thin-film encapsulation layer 60. Also, the display panel 1 may include a bending protection layer BPL located in a bending area of the substrate 10b. In this case, the support substrate 10a may include a first support substrate 10a-1 having an insertion groove 10a-1c, and a second support substrate 10a-2 separated from the first support substrate 10a-1 by an opening area 10a-1d (e.g., see FIGS. 6A-6B). In this case, a method in which the second support substrate 10a-2 is attached to the substrate 10b is the same as or similar to that described above, and thus, a detailed description thereof is omitted.

The display panel 1 may include a cushion layer CU. In this case, the cushion layer CU may include an elastic material, such as silicone, rubber, or urethane. The cushion layer CU may include a first cushion layer CU-1 and a second cushion layer CU-2 separated from each other so as to respectively correspond to the first support substrate 10a-1 and the second support substrate 10a-2. In this case, the first cushion layer CU-1 may have a groove formed to correspond to the insertion groove 10a-1c, and may be divided into a first-first cushion layer CU-1a located on a first portion 10a-1a and a first-second cushion layer CU-1b located on a second portion 10a-1b, based on the groove. In this case, the groove formed in the first cushion layer CU-1 may have a shape that is the same as or similar to that of the insertion groove shown in FIG. 6A or FIG. 6B.

In the above case, the second cushion layer CU-2 may be inserted into the insertion groove 10a-1c. In this case, an adhesive member 80 may be located on one surface of the second cushion layer CU-2 and fix the second cushion layer CU-2 to the substrate 10b.

In one or more embodiments, a separate adhesive layer may be arranged between the cushion layer CU and the support substrate 10a.

In one or more embodiments, the second cushion layer CU-2 may be located similarly to the second support substrate 10a-2 shown in FIG. 8. That is, the first cushion layer CU-1 may be arranged inside the boundary of the display area DA and the second cushion layer CU-2 may be arranged at the boundary of the display area DA.

In the one or more embodiments corresponding to FIG. 10, the cushion layer CU may be located on the first support substrate 10a-1 and the second support substrate 10a-2 after the insertion groove 10a-1c and the opening area 10a-1d (e.g., see FIGS. 6A-6B) are formed as shown in FIG. 7D. In one or more other embodiments, the cushion layer CU may be arranged to cover the insertion groove 10a-1c and the opening area 10a-1d (e.g., see FIGS. 6A-6B), and then, portions of the cushion layer CU respectively corresponding to the insertion groove 10a-1c and the opening area may be removed. In one or more embodiments, the cushion layer CU may be arranged in a shape similar to that of the protective film PF shown in FIG. 7B, and in this case, the protective film PF may be located on the cushion layer CU and the base substrate MS may be etched.

In the display device DP according to the embodiments of the present disclosure, a storage space of the display panel 1 may be reduced. In the display device DP according to the embodiments of the present disclosure, the thickness thereof may be reduced.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a support substrate comprising a first portion and a second portion that are separated from each other;
a substrate fixed to one surface of the second portion of the support substrate, and comprising a display area on the first portion of the support substrate, a peripheral area on the second portion of the support substrate, and a bending area connecting the display area to the peripheral area; and
a display portion in the display area of the substrate.

2. The display device of claim 1, wherein the first portion of the support substrate defines an insertion groove into which the second portion of the support substrate is inserted.

3. The display device of claim 2, further comprising a protective member in the insertion groove.

4. The display device of claim 1, wherein a portion of an edge of a plane of the first portion of the support substrate overlaps a planar shape of the display area.

5. The display device of claim 1, wherein at least a portion of the second portion of the support substrate overlaps the display area in a plan view.

6. The display device of claim 1, further comprising a protection layer on the substrate and corresponding to the bending area.

7. The display device of claim 1, wherein a size of a planar shape of the first portion of the support substrate is greater than a size of a planar shape of the second portion of the support substrate.

8. The display device of claim 1, wherein at least a portion of a boundary of the first portion of the support substrate is below the display area.

9. The display device of claim 1, wherein at least a portion of a boundary of the second portion of the support substrate is below the display area.

10. The display device of claim 1, wherein a boundary of the display area is inside a boundary of the first portion of the support substrate in a plan view.

11. A display device comprising:
a support substrate comprising a first portion and a second portion that are separated from each other; and
a substrate on the support substrate, and having an area between the first portion of the support substrate and the second portion of the support substrate that is bent,
wherein one surface of the second portion of the support substrate and an other surface of the second portion of the support substrate that oppose each other, are attached to the substrate.

12. The display device of claim 11, further comprising an adhesive member between the other surface of the second portion of the support substrate and the substrate.

13. The display device of claim 11, wherein the second portion of the support substrate is inside the first portion.

14. The display device of claim 11, wherein the substrate comprises a display area comprising a display portion, and a peripheral area that is adjacent to the display area.

15. The display device of claim 14, wherein at least a portion of the second portion of the support substrate overlaps the display area in a plan view.

16. The display device of claim 14, wherein a boundary of the display area is on the second portion of the support substrate.

17. The display device of claim 11, wherein the second portion of the support substrate is inside the first portion of the support substrate.

18. The display device of claim 11, further comprising a protective member between the second portion of the support substrate and the first portion of the support substrate.

19. The display device of claim 11, wherein the substrate further comprises a bending portion with filler therein.

20. A display device comprising:
a support substrate comprising a first portion and a second portion that are separated from each other;
a substrate on the first portion and the second portion of the support substrate, and comprising a display area; and
a display portion in the display area,
wherein the second portion of the support substrate is attached to the substrate, and wherein at least a portion of the second portion of the support substrate overlaps the display area in a plan view.
